(19) United States
(12) Patent Application Publication
(10) Pub. No.: US 2010/0109063 A1
(43) Pub. Date: May 6, 2010

(54) Semiconductor device having MOS gate capacitor

(75) Inventor: Yoko Hayashida, Tokyo (JP)

Correspondence Address: MCGINN INTELLECTUAL PROPERTY LAW GROUP, PLLC, 8321 OLD COURTHOUSE ROAD, SUITE 200, VIENNA, VA, 22182-3817, US

(73) Assignee: ELPIDA MEMORY, INC., Tokyo (JP)

(21) Appl. No.: 12/588,835

(22) Filed: Oct. 29, 2009

(30) Foreign Application Priority Data
Oct. 30, 2008 (JP) 2008-280066

(51) Int. Cl. H01L 27/06

(52) U.S. Cl. 257/300; 257/E27.016

(57) ABSTRACT

To provide a PMOS transistor that is arranged within an N-well formed in a P-type semiconductor substrate and that is connected to an external terminal; and an MOS gate capacitor that is positioned adjacent to the PMOS transistor and of which one end and the other end are supplied with a power supply potential and a ground potential, respectively. An N-type diffusion layer that becomes a cathode of a PNPN parasitic thyristor configured by the PMOS transistor and the MOS gate capacitor is fixed to the power supply potential. This structure does not permit turning on of the PNPN parasitic thyristor, and thus a problem that a device is broken by a latch-up phenomenon is eliminated.

### BACKGROUND OF THE INVENTION

1. Field of the Invention

The present invention relates to a semiconductor device, and, more particularly relates to a semiconductor device that includes an MOS gate capacitor connected between power supply lines.

2. Description of Related Art

In recent years downscaling and usage of lower voltage in semiconductor devices have progressed. Along with the trend, the protection against noise for semiconductor devices is increasingly becoming important. As a well known method of protecting an internal circuit from external noise intruding into semiconductor devices, there has been a method of connecting a protection device or the like to a bonding pad (external terminal).

Meanwhile, for the purpose of alleviating power supply noise and suppressing fluctuation of a power supply voltage caused by load fluctuation, a capacitive element is often connected between a power supply potential and a ground potential. For example, in Japanese Patent Application Laid-open No. 2004-165246, there is disclosed a configuration in which a bypass capacitor formed of an MOS gate capacitor is positioned below a bonding pad.

However, when an MOS gate capacitor connected between power supply lines and a PMOS transistor configuring elements such as a protection device and an output buffer are positioned adjacent to each other, a PNPN parasitic thyristor can be formed thereby. Thus, when the PNPN parasitic thyristor is turned on, a large current continues to flow by a latch-up phenomenon, and there is a possibility that a device is broken.

### SUMMARY

The present invention seeks to solve one or more of the above problems, or to improve upon those problems at least in part.

In one embodiment, there is provided a semiconductor device that includes: a first transistor of a first conductivity type that is formed in a first well of a second conductivity type formed in a semiconductor substrate of the first conductivity type and that is connected to an external terminal; and an gate capacitor that is positioned adjacent to the first transistor, and of which one end and the other end are supplied with a power supply potential and a ground potential, respectively, wherein the power supply potential is supplied to a diffusion layer of the second conductivity type that functions as a cathode of a PNPN parasitic thyristor configured by the first transistor and the gate capacitor.

According to the present invention, the diffusion layer of the second conductivity type becoming the cathode of the PNPN parasitic thyristor that is configured by the first transistor and the gate capacitor is fixed to the power supply potential, and this structure does not permit the thyristor to turn on. As a result, the problem that the device is broken by the latch-up phenomenon is eliminated. Furthermore, it becomes possible to bring the first transistor and the gate capacitor closer, and thus reduction of a chip area can be made.

### BRIEF DESCRIPTION OF THE DRAWINGS

The above features and advantages of the present invention will be more apparent from the following description of certain preferred embodiments taken in conjunction with the accompanying drawings, in which:

FIG. 1 is a schematic layout diagram of an entire configuration of a semiconductor device according to a preferred embodiment of the present invention;

FIG. 2 is a circuit diagram showing a part of the DQ terminal region 20;

FIG. 3 is a schematic plan view showing a part of the DQ terminal region 20 in an enlarged manner;

FIG. 4 is a circuit diagram showing a part of the input terminal region 30;

FIG. 5 is a schematic plan view showing a part of the input terminal region 30 in an enlarged manner;

FIG. 6 is a schematic plan view showing an example of structures of the PMOS transistor 24 and the MOS gate capacitor 41 in the DQ terminal region 20;

FIG. 7 is a schematic cross-sectional view taken along a line A-A shown in FIG. 6;

FIG. 8 is a schematic cross-sectional view showing an example of the structure of the protection device 34 and the MOS gate capacitor 41 in the input terminal region 30;

FIG. 9 is a schematic plan view showing another example of the structure of the PMOS transistor 24 and the MOS gate capacitor 41 in the DQ terminal region 20;

FIG. 10 is a schematic cross-sectional view taken along a line B-B shown in FIG. 9;

FIG. 11 is a schematic cross-sectional view showing an example of the structure of the protection device 34 and the MOS gate capacitor 41 in the input terminal region 30;

FIG. 12 is a schematic plan view showing an example in which the MOS gate capacitor 41 is positioned below the bonding pad; and

FIG. 13 is a schematic plan view showing a part of the DQ terminal region in an enlarged manner.

### DETAILED DESCRIPTION OF THE EMBODIMENTS

Preferred embodiments of the present invention will be explained below in detail with reference to the accompanying drawings.

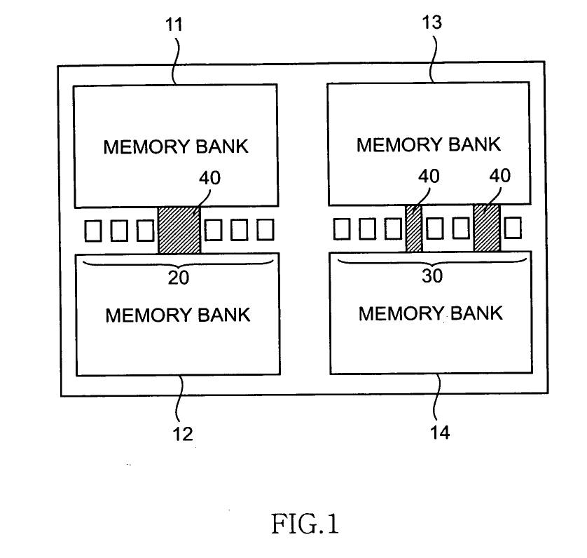

FIG. 1 is a schematic layout diagram of an entire configuration of a semiconductor device according to a preferred embodiment of the present invention.

The semiconductor device according to the present embodiment is a DRAM (Dynamic Random Access Memory), and includes a plurality of memory banks 11 to 14, a DQ terminal region 20 positioned between the memory banks 11 and 12, and an input terminal region 30 positioned between the memory banks 13 and 14, as shown in FIG. 1. In the memory banks 11 to 14, a large number of DRAM memory cells are positioned, and various types of peripheral circuits such as an address decoder and a read/write amplifier are arranged around the memory banks 11 to 14. However, these components are not directly relevant to the gist of the present invention, and thus explanations thereof will be omitted.

The DQ terminal region 20 is a region where a data input/output terminal (DQ) and power supply terminals for data input/output (VDDQ and VSSQ) are positioned. The input terminal region 30 is a region where an address terminal, a command terminal, a clock terminal, and power supply terminals (VDD and VSS) are positioned. As shown in FIG. 1, in the DQ terminal region 20 and the input terminal region 30, capacitor areas 40 are respectively arranged. In each of the capacitor areas 40, an MOS gate capacitor 41 connected between power supply lines is positioned. The MOS gate capacitor positioned in the capacitor area 40 functions as a decoupling capacitor or a bypass capacitor. As described later, the MOS gate capacitor is formed in the capacitor area 40, and thus a semiconductor substrate in the capacitor area 40 is occupied by the MOS gate capacitor. However, it is possible to utilize a layer above the semiconductor substrate as a wiring layer. A MIS gate capacitor can be used instead of the MOS gate capacitor 41.

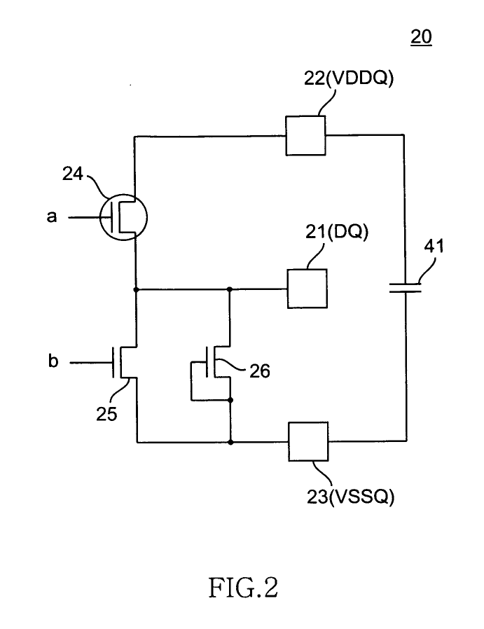

FIG. 2 is a circuit diagram showing a part of the DQ terminal region 20.

As shown in FIG. 2, in the DQ terminal region 20, the data input/output terminal 21 and the power supply terminals 22 and 23 for data input/output are included as bonding pads (external terminals). The data input/output terminal 21 is an external terminal that outputs read data and inputs write data, and is connected to drains of a PMOS transistor 24 and an NMOS transistor 25 configuring an output buffer. Gate electrodes of the PMOS transistor 24 and the NMOS transistor 25 are supplied with internal signals a and b, respectively, and thereby, a logical level of the read data output from the data input/output terminal 21 is defined. An input buffer that receives the write data is also connected to the data input/output terminal 21. However, the input buffer is omitted in FIG. 2. A MIS transistor can be used instead of the MOS transistor.

The power supply terminals 22 and 23 for data input/output are external terminals supplied with operation voltages of the PMOS transistor 24 and the NMOS transistor 25. Specifically, the power supply terminal 22 for data input/output is connected to a source of the PMOS transistor 24, and is supplied with the power supply potential VDDQ for data output from outside. The power supply terminal 23 for data input/output is connected to a source of the NMOS transistor 25, and is supplied with the ground potential VSSQ for data output from outside.

Between the data input/output terminal 21 and the power supply terminal 23 for data input/output, a protection device 26 is also connected. The protection device 26 includes a configuration that a diode-connected NMOS transistor is reversely connected between the data input/output terminal 21 and the power supply terminal 23 for data input/output, and functions to discharge ESD (electrostatic discharge) to the power supply terminal 23 for data input/output by snapback when the ESD is applied to the data input/output terminal 21.

Furthermore, between the power supply terminals 22 and for data input/output, the MOS gate capacitor 41 is connected. As described above, the MOS gate capacitor 41 is positioned in the capacitor area 40 and functions as a decoupling capacitor or a bypass capacitor.

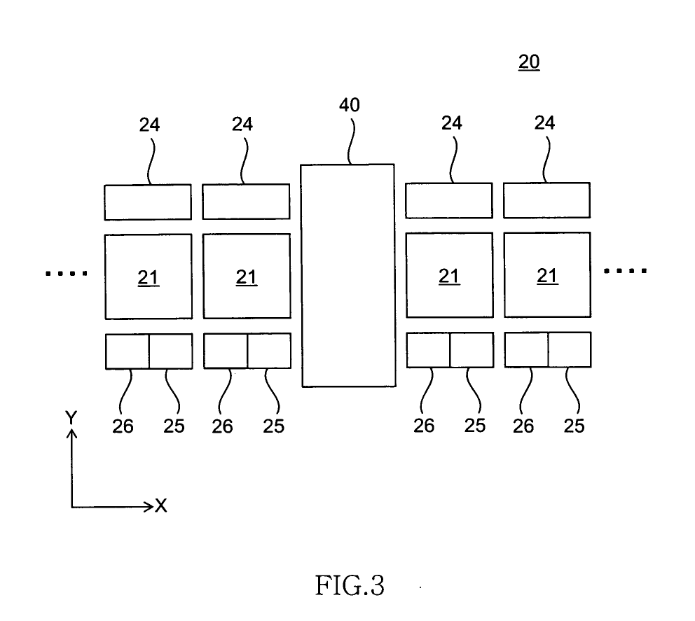

FIG. 3 is a schematic plan view showing a part of the DQ terminal region 20 in an enlarged manner.

As shown in FIG. 3, in the DQ terminal region 20, a plurality of the data input/output terminals 21 are arrayed in an X direction. On one side (the upper side of FIG. 3) in a Y direction of each of the data input/output terminals 21, each of the PMOS transistors 24 configuring the output buffer is positioned, and on the other side in the Y direction (the lower side of FIG. 3) of each of the data input/output terminals 21, each of the NMOS transistors 25 configuring the output buffer is positioned. In the X direction adjacent to the NMOS transistor 25, each of the protection devices 26 is positioned. The power supply terminals 22 and 23 for data input/output are omitted in FIG. 3.

Thus, in the DQ terminal region 20, the data input/output terminal 21, the PMOS transistor 24, the NMOS transistor 25, and the protection device 26 are regarded as one unit. A plurality of these units are arrayed in the X direction. In apart of such an array, the capacitor area 40 is intervened.

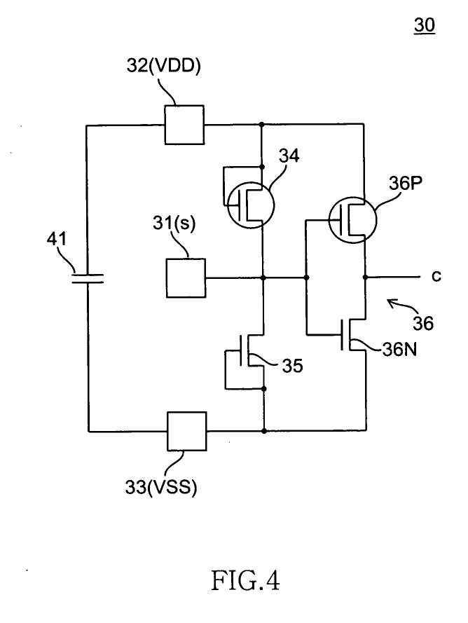

FIG. 4 is a circuit diagram showing a part of the input terminal region 30.

As shown in FIG. 4, the input terminal region 30 includes, as bonding pads (external terminals), a signal input terminal 31 and the power supply terminals 32 and 33. The signal input terminal 31 is either one of the address terminal, the command terminal, or a clock terminal, and is connected to a gate electrode of an input buffer 36. Thereby, depending on an input signal s applied to the signal input terminal 31, a logical level of an internal signal c is defined.

The power supply terminals 32 and 33 are external terminals supplied with operation voltages of various types of internal circuits including the input buffer 36. Specifically, the power supply terminal 32 is connected to a source of a PMOS transistor 36P configuring the input buffer 36, and is supplied with a power supply potential VDD from outside. The power supply terminal 33 is connected to a source of an NMOS transistor 36N configuring the input buffer 36, and is supplied with the ground potential VSS from outside.

Between the signal input terminal 31 and the power supply terminal 32, a protection device 34 is connected, and between the signal input terminal 31 and the power supply terminal 33, a protection device 35 is connected. The protection device 34 has a configuration in which a diode-connected PMOS transistor is reversely connected between the signal input terminal 31 and the power supply terminal 32, and the protection device 35 has a configuration in which a diode-connected NMOS transistor is reversely connected between the signal input terminal 31 and the power supply terminal 33. With this configuration, the protection devices 34 and 35 function to discharge the ESD to the power supply terminals 32 and 33 by snapback when the ESD is applied to the signal input terminal 31.

Furthermore, between the power supply terminals 32 and 33, the MOS gate capacitor 41 is connected. As described above, the MOS gate capacitor 41 is positioned in the capacitor area 40 and functions as a decoupling capacitor or a bypass capacitor.

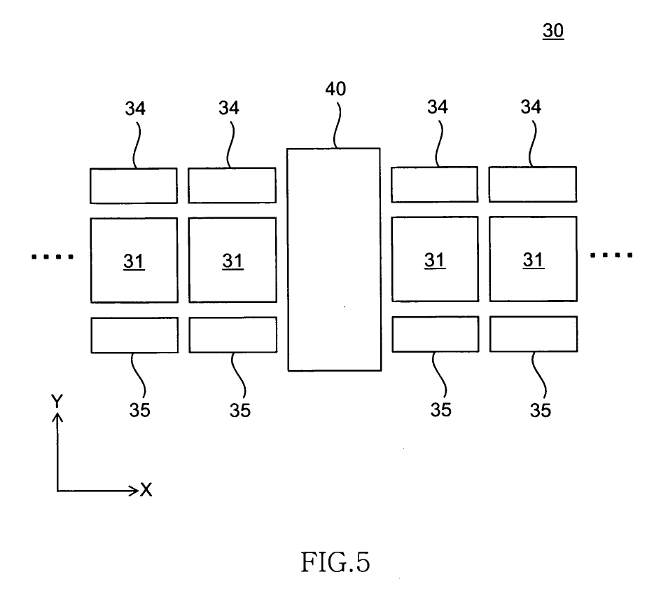

FIG. 5 is a schematic plan view showing a part of the input terminal region 30 in an enlarged manner.

As shown in FIG. 5, in the input terminal region 30, a plurality of the signal input terminals 31 are arrayed in the X direction; on one side (upper side of FIG. 5) in the Y direction of each of the signal input terminals 31, each PMOS transistor configuring the protection device 34 is positioned; and on the other side (lower side of FIG. 5) in the Y direction of each of the signal input terminals 31, each NMOS transistor configuring the protection device 35 is positioned. The power supply terminals 32 and 33 are omitted in FIG. 5.

Thus, in the input terminal region 30, the signal input terminal 31, the protection device 34, and the protection device 35 are regarded as one unit. A plurality of these units are arrayed in the X direction. In a part of such an array, the capacitor area 40 is intervened.

The structure of impurity diffusion layers in the DQ terminal region 20 and the input terminal region 30 is described next.

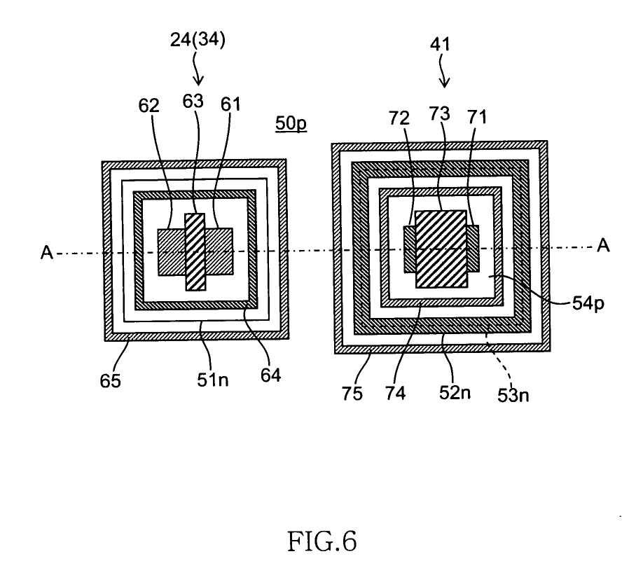

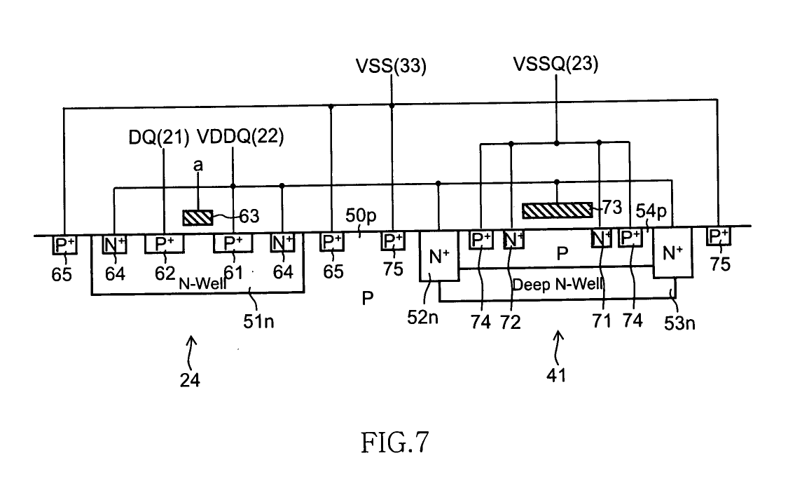

FIG. 6 is a schematic plan view showing an example of structures of the PMOS transistor 24 and the MOS gate capacitor 41 in the DQ terminal region 20, and FIG. 7 is a schematic cross-sectional view taken along a line A-A shown in FIG. 6.

As shown in FIGS. 6 and 7, the PMOS transistor 24 and the MOS gate capacitor 41 are both formed in a P-type semiconductor substrate 50p. Among the two components, the PMOS transistor 24 is arranged within an N-well 51n formed in the P-type semiconductor substrate 50p, and the MOS gate capacitor 41 is arranged in a P-type semiconductor region 54p surrounded by a ring-shaped N-type diffusion region 52n and a deep N-well 53n formed in the P-type semiconductor substrate 50p. The PMOS transistor 24 and the MOS gate capacitor 41 are positioned adjacent to each other.

More particularly, the PMOS transistor 24 is configured by a source region 61, a drain region 62, and a gate electrode 63 arranged within the N-well 51n. Needless to mention, the conductivity type of the source region 61 and the drain region 62 is P-type. The source region 61 is connected to the power supply terminal 22 for data input/output, and thereby, the power supply potential for data output VDDQ is supplied thereto. The drain region 62 is connected to the data input/output terminal 21. The gate electrode 63 is supplied with an internal signal a.

Within the N-well 51n formed therein with the PMOS transistor 24, a ring-shaped N-type diffusion region 64 is arranged to completely surround the PMOS transistor 24. The ring-shaped N-type diffusion region 64 is connected to the power supply terminal 22 for data input/output, and thereby, the N-well 51n is biased to the power supply potential for data output VDDQ. Outside the N-well 51n, a ring-shaped

P-type diffusion region 65 is arranged to completely surround the N-well 51n. The ring-shaped P-type diffusion region 65 is a channel stopper, and is connected to the power supply terminal 33 (VSS).

On the other hand, the MOS gate capacitor 41 in the DQ terminal region 20 is configured by source/drain regions 71 and 72 and a gate electrode 73 arranged within the P-type semiconductor region 54p. The conductivity type of the source/drain regions 71 and 72 is N-type, and thus the MOS gate capacitor 41 has an NMOS structure. However, the source/drain regions 71 and 72 are both connected to the power supply terminal 23 for data input/output (VSSQ), and thus the MOS gate capacitor 41 does not operate as transistors in practice. The gate electrode 73 is connected to the power supply terminal 22 for data input/output, and thereby, the power supply potential for data output VDDQ is supplied thereto.

Within the P-type semiconductor region 54p, a ring-shaped P-type diffusion region 74 is arranged to completely surround the MOS gate capacitor 41. The ring-shaped P-type diffusion region 74 is connected to the power supply terminal 23 for data input/output, and thereby, the P-type semiconductor region 54p is biased to the power supply potential VSSQ for data output. With this configuration, the gate electrode 73 to which the VDDQ is applied and the P-type semiconductor region 54p to which the VSSQ is applied are opposite via a gate dielectric film. Thereby, between the VDDQ and VSSQ, the MOS gate capacitor is applied.

Further, outside the P-type semiconductor region 54p, a ring-shaped P-type diffusion region 75 is arranged to completely surround the P-type semiconductor region 54p. The ring-shaped P-type diffusion region 75 is a channel stopper, and is connected to the power supply terminal 33 (VSS).

By the diffusion layer structure, in the PMOS transistor 24 and the MOS gate capacitor 41, a PNPN parasitic thyristor is formed. Specifically, the drain region 62 (P-type), the N-well 51n (N-type), the P-type semiconductor substrate 50p (P-type), and the ring-shaped N-type diffusion region 52n (N-type) configure the PNPN parasitic thyristor. The drain region 62 functions as an anode, the ring-shaped N-type diffusion region 52n functions as a cathode, and the P-type semiconductor substrate 50p functions as a gate.

However, in the present embodiment, the ring-shaped N-type diffusion region 52n that becomes a cathode is fixed to the power supply potential for data output VDDQ. Thus, even when noise that results in a trigger is intruded from the data input/output terminal 21 (DQ) connected to the drain region 62, the PNPN parasitic thyristor is not turned on. This eliminates a problem that the device is broken by a latch-up phenomenon. Moreover, due to the fact that the latch-up phenomenon does not occur, it becomes possible to shorten a distance between the PMOS transistor 24 and the MOS gate capacitor 41, the chip area can be reduced.

On the other hand, when the ring-shaped N-type diffusion region 52n is not present, the PNPN parasitic thyristor is formed by the drain region 62 (P-type), the N-well 51n (N-type), the P-type semiconductor substrate 50p (P-type), and the source/drain regions 71 and 72 (N-type). In this case, due to the fact that the source/drain regions 71 and 72 (N-type) that become cathodes are biased to the power supply potential VSSQ for data output, when noise that results in a trigger is intruded from the data input/output terminal 21 (DQ), the PNPN parasitic thyristor is turned on. As a result, it is probable that the latch-up occurs. On the other hand, in the present embodiment, the ring-shaped N-type diffusion region 52n is arranged and is fixed to the power supply potential for data output VDDQ, and thus such a problem will not occur.

The structure of the protection device 34 and the MOS gate capacitor 41 in the input terminal region 30 is similar to that shown in FIGS. 6 and 7. However, a voltage or a signal applied to each impurity diffusion layer differs.

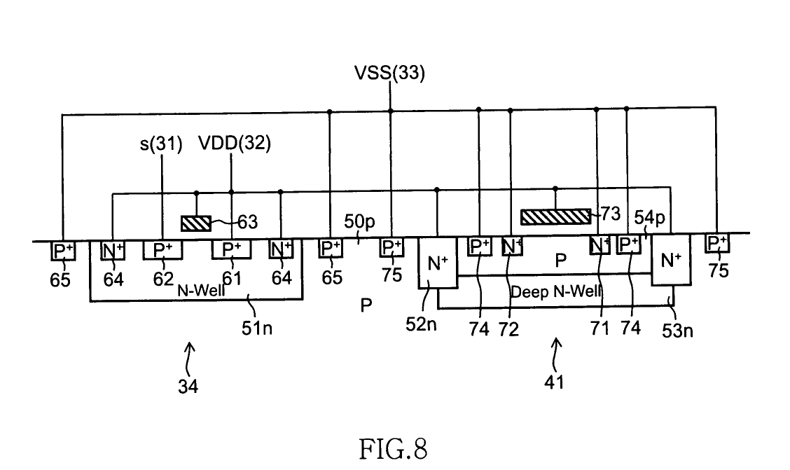

FIG. 8 is a schematic cross-sectional view showing an example of the structure of the protection device 34 and the MOS gate capacitor 41 in the input terminal region 30. As shown in FIG. 8, the structure is the same as that shown in FIG. 7. However, a voltage or a signal applied to each impurity diffusion layer differs.

To specifically describe the structure, the source region 61, the gate electrode 63, and the ring-shaped N-type diffusion region 64 of the PMOS transistor 24 configuring the protection device 34 are connected to the power supply terminal 32, and thereby, the power supply potential VDD is supplied thereto. The drain region 62 is connected to the signal input terminal 31, and thereby, the input signal s is supplied thereto. Other features are identical to those of the PMOS transistor 24 shown in FIG. 7.

The MOS gate capacitor 41 in the input terminal region 30 is so configured that the source/drain regions 71 and 72 and the ring-shaped P-type diffusion region 74 are all connected to the power supply terminal 33 (VSS) , and the gate electrode 73 is connected to the power supply terminal 32 (VDD) . Other features are identical to those in the MOS gate capacitor 41 in the DQ terminal region 20 shown in FIG. 7.

Accordingly, in the input terminal region 30, the PNPN parasitic thyristor is also formed by the protection device 34 and the MOS gate capacitor 41. However, the ring-shaped N-type diffusion region 52n that becomes a cathode is fixed to the power supply potential VDD, and thus the PNPN parasitic thyristor is not turned on.

Thus, a case that the MOS gate capacitor 41 has an NMOS structure is described as an example. However, in the present invention, the MOS gate capacitor 41 can also have a PMOS structure.

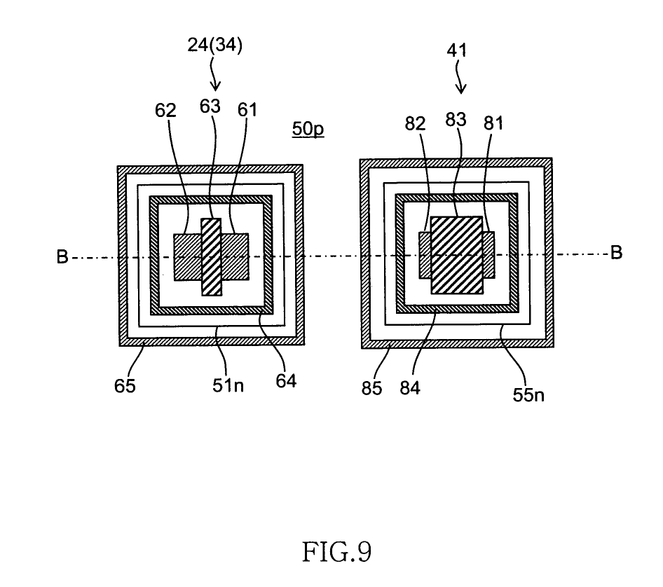

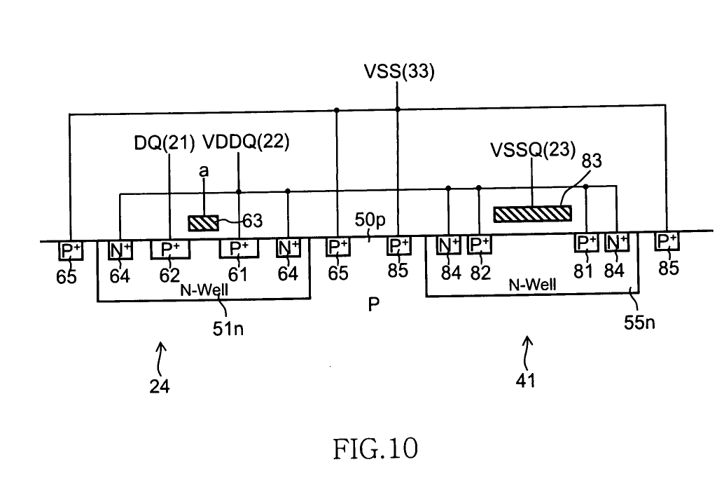

FIG. 9 is a schematic plan view showing another example of the structure of the PMOS transistor 24 and the MOS gate capacitor 41 in the DQ terminal region 20, and FIG. 10 is a schematic cross-sectional view taken along a line B-B shown in FIG. 9.

In an example shown in FIGS. 9 and 10, the structure of the MOS gate capacitor 41 differs from that in the example shown in FIGS. 6 and 7, and other features are the same as those shown in FIGS. 6 and 7. Thus, like parts are designated by like reference numerals and redundant descriptions thereof will be omitted.

As shown in FIGS. 9 and 10, the example has a PMOS structure in which the MOS gate capacitor 41 is arranged within an N-well 55n. More specifically, the MOS gate capacitor 41 is configured by source/drain regions 81 and 82 and a gate electrode 83 arranged within the N-well 55n. The conductivity type of the source/drain regions 81 and 82 is P-type and thus the MOS gate capacitor 41 has a PMOS structure. However, the source/drain regions 81 and 82 are both connected to the power supply terminal 22 for data input/output (VDDQ), and thus the MOS gate capacitor 41 does not operate as transistors in practice. The gate electrode 83 is connected to the power supply terminal 23 for data input/output, and thereby, the power supply potential VSSQ for data output is supplied thereto.

Within the N-well 55n, a ring-shaped N-type diffusion region 84 is arranged to completely surround the MOS gate capacitor 41. The ring-shaped N-type diffusion region 84 is connected to the power supply terminal 22 for data input/output, and thereby, the N-well 55n is biased to the power supply potential for data output VDDQ. With this configuration, the gate electrode 83 to which the VSSQ is applied and the N-well 55n to which the VDDQ is applied are opposite via a gate dielectric film. Thereby, between the VDDQ and VSSQ, the MOS gate capacitor is applied.

Moreover, outside the N-well 55n, a ring-shaped P-type diffusion region 85 is arranged to completely surround the N-well 55n. The ring-shaped P-type diffusion region 85 is a channel stopper, and is connected to the power supply terminal 33 (VSS).

Also in this example, the PNPN parasitic thyristor is formed by the PMOS transistor 24 and the MOS gate capacitor 41. Specifically, the drain region 62 (P-type), the N-well 51n (N-type), the P-type semiconductor substrate 50p (P-type), and the N-well 55n (N-type) configure the PNPN parasitic thyristor. The drain region 62 functions as an anode, the N-well 55n having a ring-shape functions as a cathode, and the P-type semiconductor substrate 50p functions as a gate.

However, also in this example, the N-well 55n that becomes a cathode is fixed to the power supply potential for data output VDDQ, and thus the PNPN parasitic thyristor is not turned on.

Needless to say, it is possible to apply the structure of the example to the protection device 34 and the MOS gate capacitor 41 in the input terminal region 30.

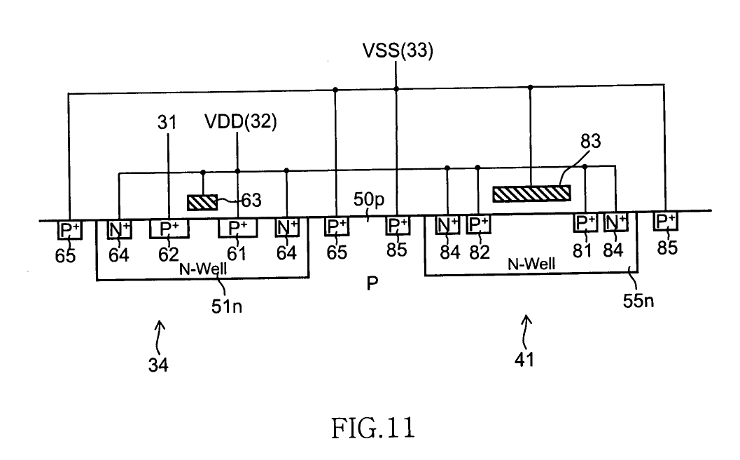

FIG. 11 is a schematic cross-sectional view showing an example of the structure of the protection device 34 and the MOS gate capacitor 41 in the input terminal region 30. As shown in FIG. 11, the structure is the same as that shown in FIG. 10. However, a voltage or a signal applied to each impurity diffusion layer differs.

To specifically describe the structure, the source region 61, the gate electrode 63, and the ring-shaped N-type diffusion region 64 of the PMOS transistor 24 configuring the protection device 34 are connected to the power supply terminal 32, and thereby, the power supply potential VDD is supplied thereto. The drain region 62 is connected to the signal input terminal 31, and thereby, the input signal s is supplied thereto. Other features are identical to those of the PMOS transistor 24 shown in FIG. 10.

The MOS gate capacitor 41 in the input terminal region 30 is so configured that the source/drain regions 81 and 82 and the ring-shaped N-type diffusion region 84 are all connected to the power supply terminal 32 (VDD), and the gate electrode 83 is connected to the power supply terminal 33 (VSS). Other features are identical to those in the MOS gate capacitor 41 in the DQ terminal region 20 shown in FIG. 10.

Accordingly, in the input terminal region 30, the PNPN parasitic thyristor is also formed by the protection device 34 and the MOS gate capacitor 41. However, similarly to the case described above, the N-well 55n that becomes a cathode is fixed to the power supply potential VDD, and thus the PNPN parasitic thyristor is not turned on.

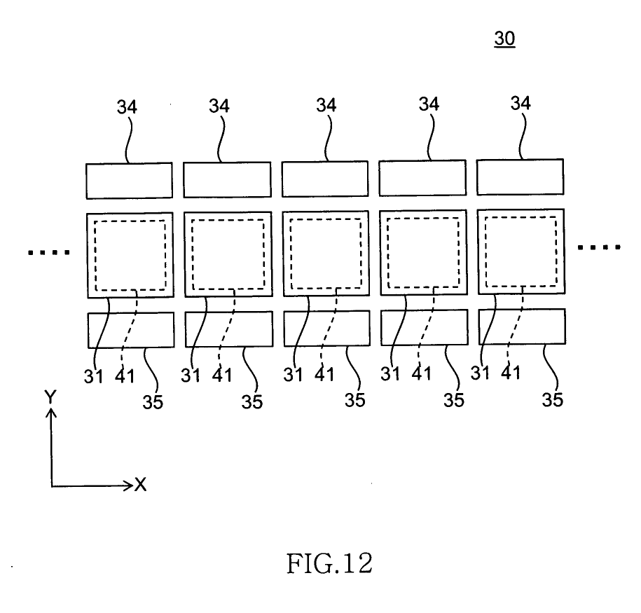

FIG. 12 is a schematic plan view showing an example in which the MOS gate capacitor 41 is positioned below the bonding pad.

FIG. 12 shows a part of the input terminal region 30 in an enlarged manner. On the semiconductor substrate positioned below the signal input terminal 31 as a bonding pad, the MOS gate capacitor 41 is positioned. In other words, above the MOS gate capacitor 41, the bonding pad as an external terminal is positioned. This arrangement eliminates necessity of arranging the capacitor area 40 separately of the bonding area, and thus it becomes possible to further increase the degree of integration. The bonding pad on the capacitor area 40 is not limited to the signal input terminal 31, and any external terminal can be used.

It is apparent that the present invention is not limited to the above embodiments, but may be modified and changed without departing from the scope and spirit of the invention.

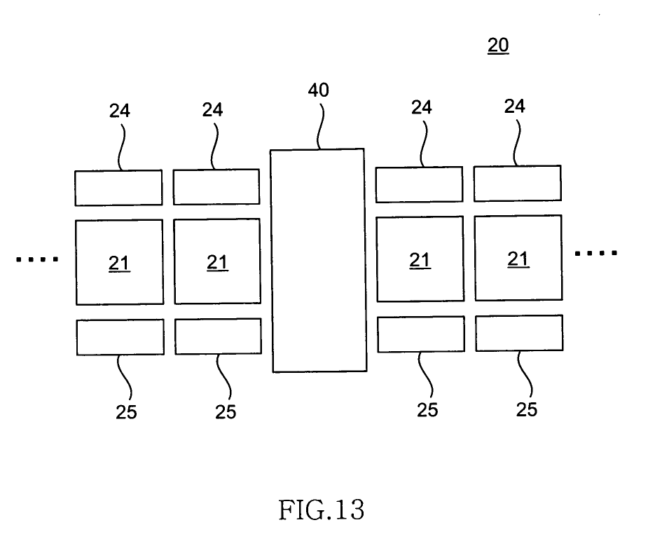

For example, in the DQ terminal region 20 shown in FIGS. 2 and 3, the protection device 26 is added only on the side of the NMOS transistor 25 configuring the output buffer. However, such a configuration is merely exemplary. Accordingly, the protection device 26 can be also added on the side of the PMOS transistor 24. Alternatively, as shown in FIG. 13, it can be configured that the protection device 26 is omitted and the output buffer itself functions as a protection device.

Moreover, in FIGS. 8 and 11, an example of a countermeasure for the PNPN parasitic thyristor configured by the protection device 34 added to the signal input terminal 31 and the MOS gate capacitor 41 has been described. It is possible to adopt a similar countermeasure for the PNPN parasitic thyristor configured by a PMOS-structured protection device added to the power supply terminals 32 and 33 and the MOS gate capacitor.

What is claimed is:

1. A semiconductor device comprising:
a first transistor of a first conductivity type that is formed in a first well of a second conductivity type formed in a semiconductor substrate of the first conductivity type and that is connected to an external terminal; and
an gate capacitor that is positioned adjacent to the first transistor, and of which one end and the other end are supplied with a power supply potential and a ground potential, respectively, wherein
the power supply potential is supplied to a diffusion layer of the second conductivity type that functions as a cathode of a PNPN parasitic thyristor configured by the first transistor and the gate capacitor.

2. The semiconductor device as claimed in claim 1, wherein
the gate capacitor has a structure of the second conductivity type, which is formed in a semiconductor region of the first conductivity type surrounded by a ring-shaped diffusion region of the second conductivity type formed in the semiconductor substrate and a deep well of the second conductivity type, and
the PNPN parasitic thyristor is configured by a source/drain region of the first transistor, the first well, the semiconductor substrate, and the ring-shaped diffusion region, and the source/drain region configures an anode and the ring-shaped diffusion region configures the cathode.

3. The semiconductor device as claimed in claim 1, wherein
the gate capacitor has a structure of the first conductivity type, which is formed in a second well of the second conductivity type formed in the semiconductor substrate, and
the PNPN parasitic thyristor is configured by a source/drain region of the first transistor, the first well, the semiconductor substrate, and the second well, and the source/drain region configures an anode and the second well configures the cathode.

4. The semiconductor device as claimed in claim 1, wherein the external terminal is a terminal that at least outputs a signal and the first transistor is an output buffer.

5. The semiconductor device as claimed in claim 1, wherein the external terminal is a terminal that inputs a signal or is a power supply terminal, and the first transistor is a protection device.

6. The semiconductor device as claimed in claim 1, wherein the external terminal is positioned on the gate capacitor.

7. A semiconductor device comprising:
a semiconductor substrate of a first conductivity type, and supplied with a first power potential;
a first well of a second conductivity type in the semiconductor substrate, and supplied with a second power potential;
a first transistor including first and second diffusion regions of the first conductivity type in the first well, and one of the first and second diffusion regions being connected to an external terminal;
a second well of the second conductivity type in the semiconductor substrate provided such that the first and second wells sandwiches a part of the semiconductor substrate, and supplied with the second power potential; and
a transistor type capacitor provided inside the second well,
wherein the semiconductor substrate, the first well, the one of the first and second regions, and the second well may cooperate with one another to form a parasitic thyristor, and a cathode of the parasitic thyristor is supplied with the second power potential.

8. The semiconductor device as claimed in claim 7, further comprising a third well of the first conductivity type being surrounded by the second well, wherein the transistor type capacitor is provided in the third well, and the transistor type capacitor is formed of a transistor of the second conductivity type.

9. The semiconductor device as claimed in claim 7, wherein the transistor type capacitor is provided in the second well, and the transistor capacitor is formed of a transistor of the first conductivity type.

10. The semiconductor device as claimed in claim 7, wherein the cathode of the thyristor is comprised of the second well.
